(19) United States
(12) Patent Application Publication
(10) Pub. No.: US 2019/0011770 A1
(43) Pub. Date: Jan. 10, 2019

(54) METHOD OF MANUFACTURING NANOWIRE GRID POLARIZER

(71) Applicant: SHENZHEN CHINA STAR OPTOELECTRONICS TECHNOLOGY CO., LTD., Shenzhen, Guangdong (CN)

(72) Inventor: Jun HOU, Shenzhen, Guangming (CN)

(21) Appl. No.: 15/569,714

(22) PCT Filed: Jul. 28, 2017
(86) PCT No.: PCT/CN2017/095037

§ 371 Date: Oct. 26, 2017

(30) Foreign Application Priority Data
Jul. 6, 2017 (CN) 201710547634.2

(51) Int. Cl. G02F 1/1335; G03F 7/00; G03F 7/16; C25D 5/02

(52) U.S. Cl. CPC G02F 1/133528; G03F 7/0002; G02F 2001/133548; C25D 5/02; G03F 7/164

(57) ABSTRACT

The present disclosure provides a method of manufacturing a nanowire grid polarizer, including the steps as follows: S1, providing a nanoimprint mold and filling the nanoimprint mold by using a photoresist material to obtain a nanoimprint component; S2, pairing the nanoimprint component and a conductive substrate to cure the photoresist material on a surface of the conductive substrate, removing the nanoimprint mold and forming a nano photoresist array on the surface of the conductive substrate; wherein the nano photoresist array has a first void array therebetween; and S3, depositing a metal in the first void array by using an electrodeposition method and removing the nano photoresist array, and forming a nanowire grid on the surface of the conductive substrate to obtain the nanowire grid polarizer. According to the manufacturing method of the present disclosure, an etching process is avoided, and metals of different materials and different sizes may be deposited according to the needs, moreover, a growth speed of the metal may be controlled by adjusting the electrodeposition parameters, and it is easy to obtain the nanowire grid with a short cycle and a high depth-to-width ratio, thereby obtaining a better polarizing effect in application.

### TECHNICAL FIELD

The present disclosure belongs to a LCD manufacturing technical field, and particularly, relates to a method of manufacturing a nanowire grid polarizer.

### BACKGROUND ART

A LCD (Liquid Crystal Display), as a platform and a carrier for information exchange, carries transmission of a large amount of information, performs a more and more important function under a social background of development and progress of the technology, and gradually becomes a key point of attention to people; and people have more and more expectations for new display modes and display effects. A polarizing plate, as an important component of the LCD, may absorb the light in a direction perpendicular to a polarizing axis, and only makes the light parallel with a polarizing axis direction pass through, thereby converting natural light into straight polarized light. However, more than 50% of light will be lost in this way, which greatly reduces the overall transmittance of the LCD.

A nanowire grid can transmit incident light of which a direction of the electric field is perpendicular to the wire grid direction, while reflect the light of which the direction of the electric field is parallel to the wire grid direction. Based on the working principle, the reflected light may be reused through the manners of adding anti-reflection films and the like, and thus, the ability of the nanowire grid polarizer to transmit the incident light is much greater than that of the conventional polarizer, the transmittance thereof may be up to more than 90%, and the contrast is also as high as 10000:1, which may greatly improve the transmittance and contrast of the LCD to meet the requirements of high transmittance and high contrast in the market.

The polarizing characteristics of the nanowire grid is decided by the material and the structure of the wire grid, and the structure parameters of the wire grid mainly include wire grid linewidth, wire grid depth, wire grid aspect ratio and so on. When the wire grid aspect ratio is small enough, and is far less than the wavelength range of the incident light, the wire grid can reflect almost all of the light of which the electric field vector component vibrates parallel to the wire grid, so that almost all of the light of which the electric field vector component is perpendicular to the wire grid is transmitted, and the smaller the wire grid aspect ratio is, the better the polarizing effect is. Therefore, how to obtain a sufficiently small wire grid aspect ratio and an appropriate depth-to-width ratio becomes the key to manufacturing the nanowire grid. The current main-stream manufacturing method is using dry-etching, of which the principle is bombarding a wire grid material using high energy plasma, so that the material molecules without PR protection escape, to produce an etching effect. The etching of this method is accurate and a nanowire grid with a relatively large depth-to-width ratio can be obtained, but the energy consumption is too large and the equipment is expensive.

### SUMMARY

In order to solve the above problems existing in the prior art, the present disclosure adopts the following technical solutions:

a method of manufacturing a nanowire grid polarizer, including:

S1, providing a nanoimprint mold and filling the nanoimprint mold by using a photoresist material to obtain a nanoimprint component;

S2, pairing the nanoimprint component and a conductive substrate to cure the photoresist material on a surface of the conductive substrate, removing the nanoimprint mold and forming a nano photoresist array on the surface of the conductive substrate; wherein the nano photoresist array has a first void array therebetween; and

S3, depositing a metal in the first void array by using an electrodeposition method and removing the nano photoresist array, and forming a nanowire grid on the surface of the conductive substrate to obtain the nanowire grid polarizer.

Furthermore, a specific method of the step S2 includes:

pairing the nanoimprint component and the conductive substrate and pressing the nanoimprint component at a temperature higher than a melting point of the photoresist material, so that the photoresist material is in contact with the conductive substrate;

adjusting the temperature to be lower than the melting point of the photoresist material, so that the photoresist material is cured on the surface of the conductive substrate; and

removing the nanoimprint mold and forming the nano photoresist array on the surface of the conductive substrate.

Furthermore, the conductive substrate includes a substrate and a conductive layer disposed on the substrate.

Furthermore, the substrate is selected from any one of a glass substrate, a PI film or a PET film; and a material of the conductive layer is selected from any one of ITO, graphene and transparent conductive material.

Furthermore, a specific method of the step S3 includes:

taking a bulk material of the metal as an anode and the conductive layer as a cathode, and dipping the anode and the cathode in an electrolyte;

applying a direct current voltage between the anode and the cathode, and depositing the metal in the first void array; and

after the metal is deposited, removing the nano photoresist array, and forming the nanowire grid on the surface of the conductive substrate to obtain the nanowire grid polarizer; wherein a material of the nanowire grid has a reduction potential higher than that of the material of the conductive layer.

Furthermore, the electrolyte contains an inorganic salt of the metal, a surfactant and a leveling agent.

Furthermore, the material of the conductive layer is ITO, the material of the anode is Au, and the inorganic salt of the metal is AuCl₃; or the material of the conductive layer is ITO, the material of the anode is Ag, and the inorganic salt of the metal is AgCl.

Furthermore, the surface of the nanoimprint mold has a second void array, and the photoresist material is filled in the second void array to form the nanoimprint component.

The present disclosure adopts a nanoimprint technology to manufacture the nano photoresist array on the conductive substrate, then deposits metal in the first void array formed by the nano photoresist array through the electrodeposition method to form the nanowire grid, and obtains the nanowire grid polarizer after removing the nano photoresist array; and the process of the manufacturing method is simply and the energy consumption is lower. According to the manufacturing method of the present disclosure, an etching process in a traditional nanoimprint process is avoided, and metals of different materials and different sizes can be deposited according to the needs. Moreover, a growth speed of the metal may be controlled by adjusting the electrodeposition parameters, and it is easy to obtain the nanowire grid with a short cycle and a high depth-to-width ratio, thereby obtaining a better polarizing effect when the nanowire grid polarizer is applied into the LCD.

### BRIEF DESCRIPTION OF THE DRAWINGS

The above and other aspects, characteristics and advantages of embodiments of the present disclosure will become more apparent, by the following descriptions taken in conjunction with the accompanying drawings, in which:

FIG. 1 is a step flowchart of a method of manufacturing a nanowire grid polarizer in accordance with an embodiment of the present disclosure; and

FIGS. 2-9 are process flowcharts of a method of manufacturing a nanowire grid polarizer in accordance with an embodiment of the present disclosure.

### DETAILED DESCRIPTION OF EXEMPLARY EMBODIMENTS

Embodiments of the present disclosure will be described in detail below by referring to the accompany drawings. However, the present disclosure can be implemented in many different forms, and the present disclosure should not be constructed to be limited to the specific embodiment set forth herein. Instead, these embodiments are provided for explaining the principle and actual application of the present disclosure, so that those skilled in the art would understand various embodiments of the present disclosure and modifications which are suitable for specific intended applications. In the drawings, in order to describe clearly, the shapes and sizes of the components may be exaggerated, and the same reference signs will always be used to indicate the same or similar components.

It will be understood that, although the terms “first”, and “second” can be used herein to describe a variety of structures, these structures should not be limited by these terms. These terms are only used to separate one structure from another.

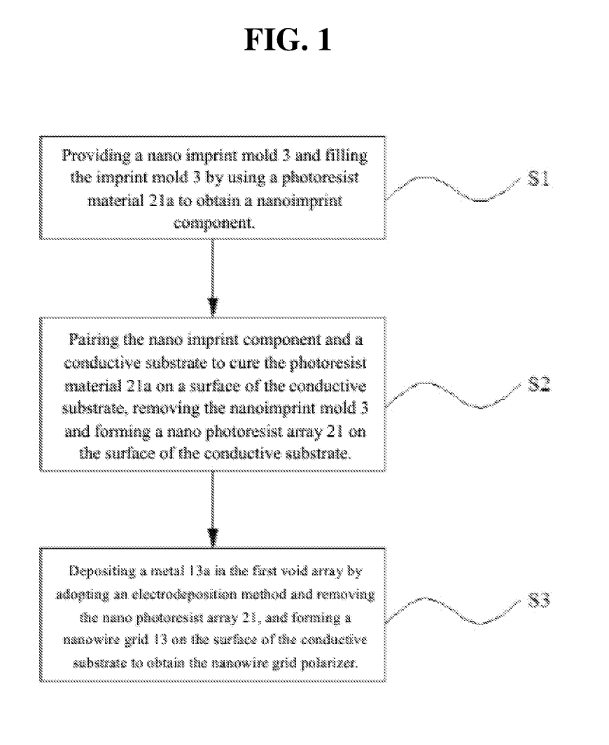

The present disclosure provides a method of manufacturing a nanowire grid polarizer, referring to FIG. 1 for details, which includes:

Step S1, providing a nanoimprint mold 3 and filling the nanoimprint mold 3 by using a photoresist material 21a to obtain a nanoimprint component.

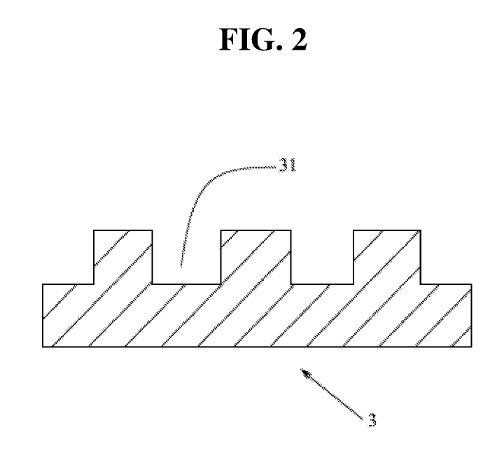

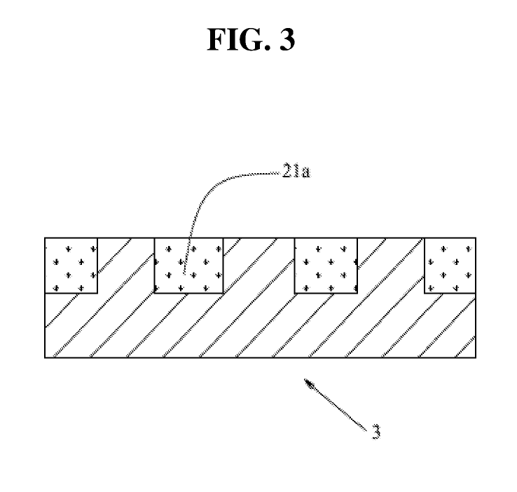

To be specific, a surface of the nanoimprint mold 3 has a second void array formed by several second voids 31, the photoresist material 21a is filled in the second void array to form the nanoimprint component, as shown in FIGS. 2 and 3.

Step S2, pairing the nanoimprint component and a conductive substrate to cure the photoresist material 21a on a surface of the conductive substrate, removing the nanoimprint mold 3 and forming a nano photoresist array 21 on the surface of the conductive substrate.

Generally, the conductive substrate includes a substrate 11 and a conductive layer 12 formed on the substrate 11; the substrate 11 may be selected from any one of a glass substrate, a PI film or a PET film; and a material of conductive layer 12 is selected from any one of ITO, graphene and transparent conductive material; and the selections of the substrate 11 and the conductive layer 12 are omitted here, and those skilled in the art may refer to the prior art.

To be specific, the nano photoresist array 21 is formed by configurations of several nano photoresists, and a first void array is formed between the nano photoresists formed by several first voids 22.

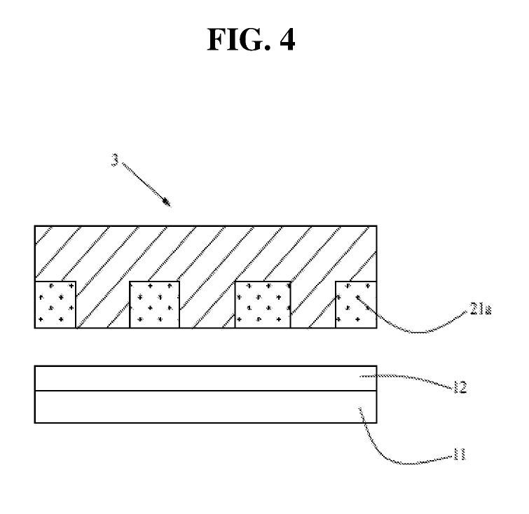

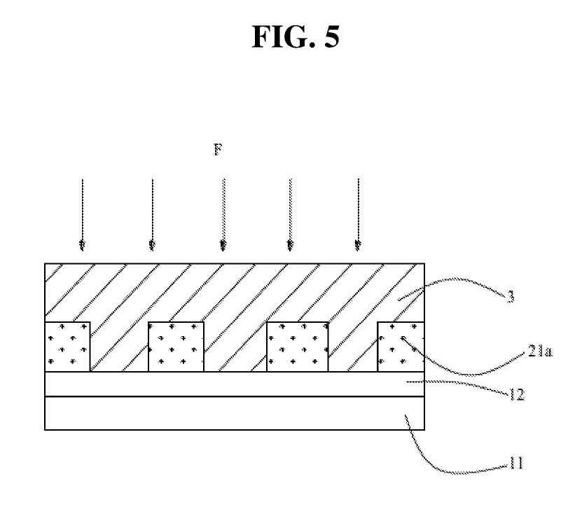

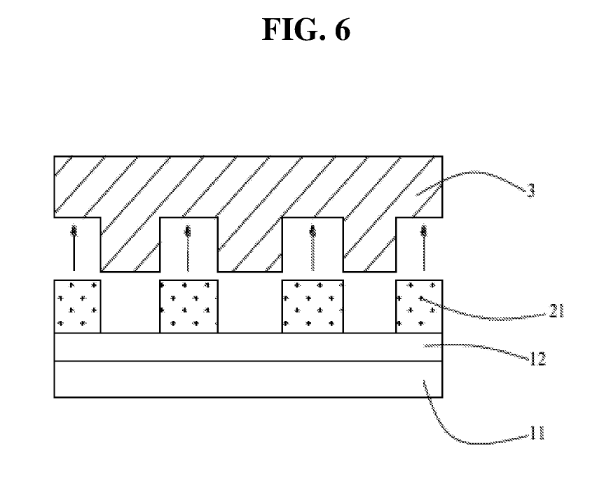

To be more specific, it is preferable to form the nano photoresist array using the following methods: (1) pairing the nanoimprint component and the conductive substrate and pressing the nanoimprint component at a temperature higher than a melting point of the photoresist material 21a, so that the photoresist material 21a is in contact with the conductive layer 12 in the conductive substrate; (2) adjusting the temperature to be lower than the melting point of the photoresist material 21a, so that the photoresist material 21a is cured on the surface of the conductive layer 12; and (3) removing the nanoimprint mold 3 and forming the nano photoresist array 21 on the surface of the conductive substrate, and referring to FIGS. 4-6 for details, in FIG. 5, the arrows represent the directions in which the pressure F is applied, and in FIG. 6, the arrows represent the directions in which the nanoimprint mold 3 is removed.

Step S3, depositing a metal 13a in the first void array by using an electrodeposition method and removing the nano photoresist array 21, and forming a nanowire grid 13 on the surface of the conductive substrate to obtain the nanowire grid polarizer.

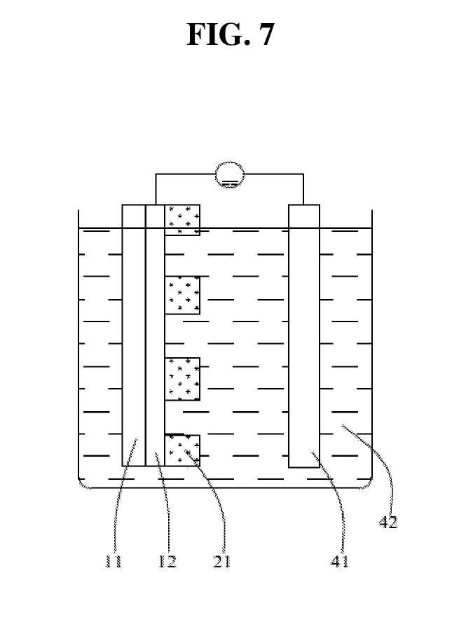

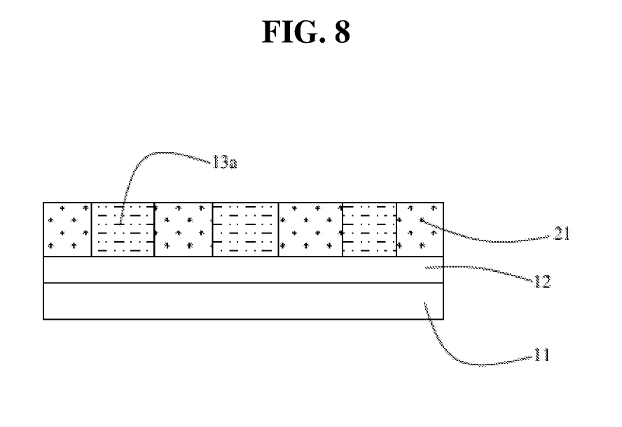

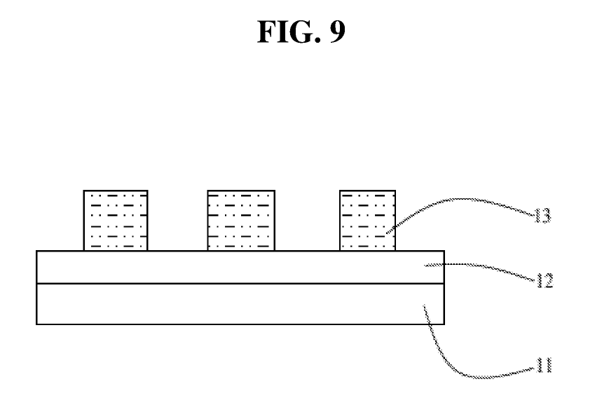

To be specific, the following methods are referred to: (1) taking a bulk material of the pre-deposited metal as an anode 41 and the conductive layer 12 as a cathode, and dipping the anode 41 and the cathode in an electrolyte 42; (2) applying a direct current voltage between the anode 41 and the cathode, and depositing the metal 13a in the first void array; and (3) after the metal 13a is deposited, taking the conductive substrate out of the electrolyte 42 and removing the nano photoresist array 21, and forming the nanowire grid 13 on the surface of the conductive substrate to obtain the nanowire grid polarizer, as shown in FIGS. 7-9.

Generally, the electrolyte contains an inorganic salt of the metal, a surfactant and a leveling agent.

The process of the above electrodeposition is explained by taking that the material of the conductive layer 12 is ITO, the material of the anode 41 is Au, and the inorganic salt of the metal is AuCl₃ as an example; wherein a reduction potential of In in ITO is −0.3382 V, a reduction potential of Sn is −0.1364 V, while a reduction potential of Au is 1.42 V; and after the direct current voltage is applied between the Au anode and the ITO cathode, the Au anode undergoes an oxidation reaction, and the Au atom loses electrons, becomes Au³⁺ and go into the electrolyte 42, meanwhile, Au³⁺ in the electrolyte 42 obtains electrons on the surface of the ITO cathode and undergoes a reduction reaction to form metal Au crystal nucleuses and grow to be filled in the first void 22, and after the metal Au is deposited, the conductive substrate is taken out of the electrolyte 42 and the nano photoresist array 21 on the surface thereof is removed, the nanowire grid 13 may be obtained, and the nanowire grid polarizer is formed by the substrate 11 and the conductive layer 12 and the nanowire grid 13 on the surface of the substrate 11. Of course, when the material of the conductive layer 12 is ITO, the material of the anode 41 may also be Ag (of which a reduction potential is 0.7996 V) and the inorganic salt of the corresponding metal is AgCl. Thus, in the process of the electrodeposition, it needs to control the reduction potential of the material of the nanowire grid 13 to be higher than that of the material of the conductive layer 12.

It can be seen from the above manufacturing process, the process of the method of manufacturing the nanowire grid polarizer in accordance with the embodiment of the present disclosure is simple and the energy consumption is lower. Meanwhile, the manufacturing method avoids an etching process in a traditional nanoimprint process, and the metal 13a of different materials and different sizes can be deposited according to the needs, moreover, the nanowire grid 13 with short cycle and high depth-to-width ratio may be obtained by adjusting the electrodeposition parameters to control the growth speed of the metal 13a, and by manufacturing the nanoimprint mold 3 having the second void array of different cycles and different depths, thereby obtaining a better polarizing effect when the nanowire grid polarizer is applied into the LCD.

Although the present invention is described with reference to the specific exemplary embodiment of the present invention, it will be understood by those of ordinary skilled in the art that various changes in form and details may be made therein without departing from the spirit and scope of the present invention as defined by the following claims and its equivalents.

What is claimed:

1. A method of manufacturing a nanowire grid polarizer, comprising the steps as follows:
S1, providing a nanoimprint mold and filling the nanoimprint mold by using a photoresist material to obtain a nanoimprint component;
S2, pairing the nanoimprint component and a conductive substrate to cure the photoresist material on a surface of the conductive substrate, removing the nanoimprint mold and forming a nano photoresist array on the surface of the conductive substrate; wherein the nano photoresist array has a first void array therebetween; and
S3, depositing a metal in the first void array by using an electrodeposition method and removing the nano photoresist array, and forming a nanowire grid on the surface of the conductive substrate to obtain the nanowire grid polarizer.

2. The manufacturing method of claim 1, wherein the step S2 comprises:
pairing the nanoimprint component and the conductive substrate and pressing the nanoimprint component at a temperature higher than a melting point of the photoresist material, so that the photoresist material is in contact with the conductive substrate;
adjusting the temperature to be lower than the melting point of the photoresist material, so that the photoresist material is cured on the surface of the conductive substrate; and
removing the nanoimprint mold and forming the nano photoresist array on the surface of the conductive substrate.

3. The manufacturing method of claim 1, wherein, the conductive substrate comprises a substrate and a conductive layer disposed on the substrate.

4. The manufacturing method of claim 3, wherein the substrate is selected from any one of a glass substrate, a PI film or a PET film; and a material of the conductive layer is selected from any one of ITO, graphene and transparent conductive material.

5. The manufacturing method of claim 3, wherein the step S3 comprises:
taking a bulk material of the metal as an anode and the conductive layer as a cathode, and dipping the anode and the cathode in an electrolyte;
applying a direct current voltage between the anode and the cathode, and depositing the metal in the first void array; and
after the metal is deposited, removing the nano photoresist array, and forming the nanowire grid on the surface of the conductive substrate to obtain the nanowire grid polarizer; wherein a material of the nanowire grid has a reduction potential higher than that of the material of the conductive layer.

6. The manufacturing method of claim 5, wherein the electrolyte contains an inorganic salt of the metal, a surfactant and a leveling agent.

7. The manufacturing method of claim 6, wherein the material of the conductive layer is ITO, the material of the anode is Au, and the inorganic salt of the metal is AuCl₃; or
the material of the conductive layer is ITO, the material of the anode is Ag, and the inorganic salt of the metal is AgCl.

8. The manufacturing method of claim 2, wherein, the conductive substrate comprises a substrate and a conductive layer disposed on the substrate.

9. The manufacturing method of claim 8, wherein the substrate is selected from any one of a glass substrate, a PI film or a PET film; and a material of conductive layer is selected from any one of ITO, graphene and transparent conductive material.

10. The manufacturing method of claim 8, wherein the step S3 comprises:
taking a bulk material of the metal as an anode and the conductive layer as a cathode, and dipping the anode and the cathode in an electrolyte;
applying a direct current voltage between the anode and the cathode, and depositing the metal in the first void array; and
after the metal is deposited, removing the nano photoresist array, and forming the nanowire grid on the surface of the conductive substrate to obtain the nanowire grid polarizer; wherein a material of the nanowire grid has a reduction potential higher than that of the material of the conductive layer.

11. The manufacturing method of claim 10, wherein the electrolyte contains an inorganic salt of the metal, a surfactant and a leveling agent.

12. The manufacturing method of claim 11, wherein the material of the conductive layer is ITO, the material of the anode is Au, and the inorganic salt of the metal is AuCl₃; or
the material of the conductive layer is ITO, the material of the anode is Ag, and the inorganic salt of the metal is AgCl.

13. The manufacturing method of claim 1, wherein the surface of the nanoimprint mold has a second void array, and the photoresist material is filled in the second void array to form the nanoimprint component.
